(19) United States
(12) Patent Application Publication
(10) Pub. No.: US 2021/0365075 A1
(43) Pub. Date: Nov. 25, 2021

(54) HINGE SWITCHES

(71) Applicant: Hewlett-Packard Development Company, L.P., Spring, TX (US)

(72) Inventors: Te-Yueh Lin, Taipei City (TW); Chien Chung Chien, Taipei City (TW); Li-Che Lu, Taipei City (TW)

(73) Assignee: Hewlett-Packard Development Company, L.P., Spring, TX (US)

(21) Appl. No.: 17/053,165

(22) PCT Filed: Sep. 4, 2018
(86) PCT No.: PCT/US2018/049326

§ 371 Date: Nov. 5, 2020

(51) Int. Cl. G06F 1/16; H05K 5/02

(52) U.S. Cl. CPC G06F 1/1681; G06F 1/1616; H05K 5/0247; H05K 5/0226; H05K 5/0239; G06F 1/1677

(57) ABSTRACT

A computing device may include a lid, a base, and a hinge switch. The hinge switch includes a first electrical contact coupled to the lid, and a second electrical contact coupled to the base. The second electrical contact is axially alignable with the first electrical contact to form a physical connection. The formation of the physical connection is to define a position of the lid relative

### BACKGROUND

Computing devices of varying types are ubiquitous throughout the world as tools that increase efficiency in carrying out sequences of arithmetic or logical operations automatically via computer programming. The ability to carry out processes within a computing device at high speed increases a user's ability to more effectively perform a myriad of tasks. Computing devices come in many form factors including laptop, desktop, and table form factors, among others. These different form factors provide access to computing resources in a myriad of environmental situations.

### BRIEF DESCRIPTION OF THE DRAWINGS

The accompanying drawings illustrate various examples of the principles described herein and are part of the specification. The illustrated examples are given merely for illustration, and do not limit the scope of the claims.

FIG. 1 is a block diagram of a computing device including a hinge switch, according to an example of the principles described herein.

FIG. 2 is a block diagram of a computing device including a hinge switch, according to an example of the principles described herein.

FIG. 3 is a perspective view of a laptop computing device, according to an example of the principles described herein.

FIG. 4 is a perspective view of a hinge switch in a closed orientation, according to an example of the principles described herein.

FIG. 5 is a perspective view of a hinge switch in an opened orientation, according to an example of the principles described herein.

FIG. 6 is an elevational view of a hinge switch in a closed orientation, according to an example of the principles described herein.

FIG. 7 is an elevational view of a hinge switch in an opened orientation, according to an example of the principles described herein.

FIG. 8 is a block diagram of a computing device including logic to detect activation and deactivation of a hinge switch, according to an example of the principles described herein.

Throughout the drawings, identical reference numbers designate similar, but not necessarily identical, elements. The figures are not necessarily to scale, and the size of some parts may be exaggerated to more clearly illustrate the example shown. Moreover, the drawings provide examples and/or implementations consistent with the description; however, the description is not limited to the examples and/or implementations provided in the drawings.

### DETAILED DESCRIPTION

Laptop computing devices provide a user with a computing platform that provides mobility while maintaining large amounts of computing power and capabilities as well as input and output devices that allow a user to interact with the laptop computing device. Laptop computing devices include hinges that allow for the laptop computing device to be opened and provided increase surface area from which data may be input to the computing device and output to a user.

Examples described herein provide a computing device. The computing device may include a lid, a base, and a hinge switch. The hinge switch includes a first electrical contact coupled to the lid, and a second electrical contact coupled to the base. The second electrical contact is axially alignable with the first electrical contact to form a physical connection. The formation of the physical connection is to define a position of the lid relative to the base.

The computing device may also include a hinge and a hinge pin. The first electrical contact is coupled to a first substrate that is rotatable around the hinge pin. The second electrical contact is coupled to a second substrate, the second substrate being coupled to the hinge pin. The first electrical contact and the second electrical contact are rotatable about the same axis as the hinge coupled between the lid and the base rotates.

The computing device may also include a controller including a general-purpose input/output (GPIO) pin. The first electrical contact is electrically coupled to the GPIO pin. The second electrical contact is electrically coupled to ground. The first electrical contact is aligned with the second electrical contact to establish a physical and electrical connection when the computing device is in a closed configuration. The establishment of the electrical connection is to complete a circuit to the GPIO to indicate that the computing device is in the closed configuration.

The computing device may include a first arm rotatably coupled to the hinge pin. The first substrate is coupled to the first arm. A second arm is coupled to the hinge pin. The first arm is coupled to the lid of the computing device. The second arm is coupled to the base of the computing device. The first electrical contact is offset from the second electrical contact when the computing device is in an open configuration. The offset is to create an open circuit with respect to the GPIO to indicate that the computing device is in the open configuration. The second electrical contact includes a protrusion that abuts the first electrical contact when the first electrical contact and the second electrical contact establishes a physical connection.

Examples described herein provide a computing device includes a lid portion, a base portion, a hinge coupling the lid portion and the base portion, and a hinge switch coupled to the hinge. The hinge switch includes a first electrical contact, and a second electrical contact axially alignable with the first electrical contact. A physical engagement of the first electrical contact and the second electrical contact is to define a closed state of the computing device, and a physical separation of the first electrical contact and the second electrical contact is to define an opened state of the computing device.

The first electrical contact is coupled to a first substrate. The first electrical contact is electrically coupled to a general-purpose input/output (GPIO) pin of a controller, and the second electrical contact is coupled to a second substrate. The second electrical contact establishes an electrical contact to ground. The first electrical contact and the second electrical contact are physically engaged when the first substrate and the second substrate rotatably align the first electrical contact and the second electrical contact when the computing device is in a closed configuration. The physical engagement of the first electrical contact and the second electrical contact completes a circuit to the GPIO to indicate that the computing device is in the closed configuration.

The first substrate is rotatably disposed around a hinge pin. The second substrate is coupled to the hinge pin. The first substrate and the second substrate rotate about the same axis relative to one another to physically couple and offset the first electrical contact and the second electrical contact. The computing device includes a state module to determine a state of the computing device based on a signal sent to the GPIO of the controller. The state is the opened state or the closed state.

The hinge includes a hinge pin. The first substrate is rotatable around the hinge pin and the second substrate being coupled to the hinge pin. The second substrate remains stationary as the first substrate rotates with an arm coupling the lid portion and the first substrate. The arm includes a void defined therein through which the hinge pin is extended. The arm is rotatably disposed about the hinge pin.

Examples described herein also provide a non-transitory computer readable storage medium including instructions that when executed cause a controller of a computing device to monitor a position of a lid of the computing device relative to a base of the computing device via a hinge switch. The hinge switch includes a first electrical contact, and a second electrical contact. In response to a determination that the hinge switch is activated, the instructions that when executed cause a controller of a computing device to determine that the position of a lid relative to the base is in a closed state. The hinge switch is activated when the first electrical contact is in physical contact with the second electrical contact to form an electrical connection. In response to a determination that the hinge switch is deactivated, the instructions that when executed cause a controller of a computing device to determine that the position of the lid relative to the base is in an opened state. The hinge switch is deactivated when the first electrical contact is offset from the second electrical contact.

Monitoring the position of the lid of the computing device includes with a basic input/output system (BIOS), monitoring a status at a general-purpose input/output (GPIO) pin of a controller for the first electrical contact physically contacting and physically offset from with the second electrical contact. The computer program product includes instructions that when executed cause the controller of the computing device to assert a signal to the GPIO pin of the controller when the hinge switch is activated, and activate the display device in response to a determination that the hinge switch is deactivated.

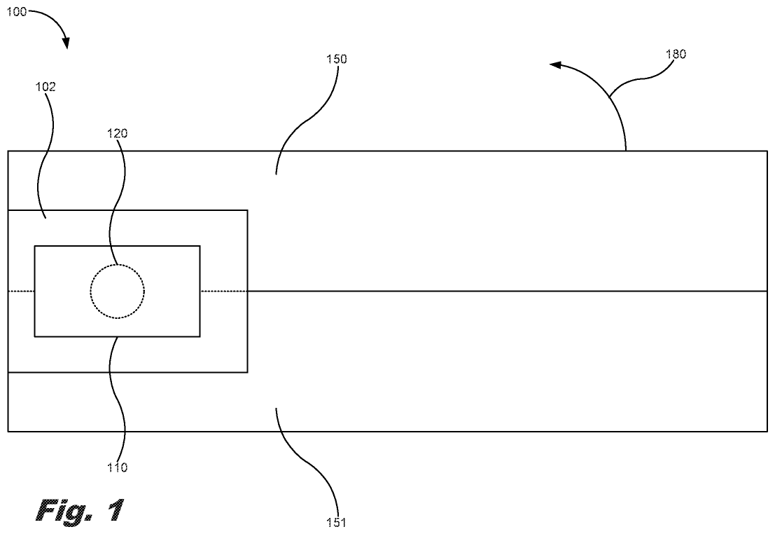

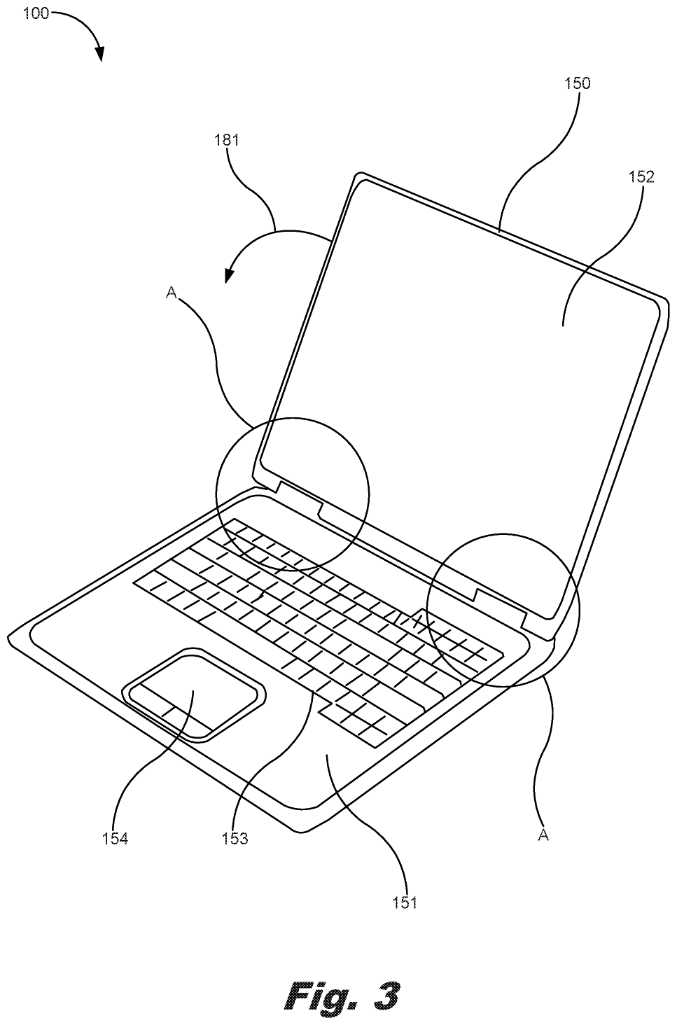

Turning now to the figures, FIG. 1 is a block diagram of a computing device (100) including a hinge switch (102), according to an example of the principles described herein. Further, FIG. 3 is a perspective view of a laptop computing device (100), according to an example of the principles described herein. The computing device (100) may include a lid (150), and a base (151). The lid (150) and base (151) serve as the elements of the laptop computing device (100) that house the input and output elements of the computing device. For example, the lid (150) may serve as a housing for a display device (FIG. 3, 152) such as a liquid crystal display (LCD) device or a light-emitting diode (LED) display device. The base (151) may be a housing for a number of computer hardware elements such as a central processing unit (CPU), a controller, a graphics processing unit (GPU), circuits, computer chips, sound cards, memory (RAM), a motherboard, a power supply, input devices such as keyboards (153) and touchpads (154), output devices, and other elements.

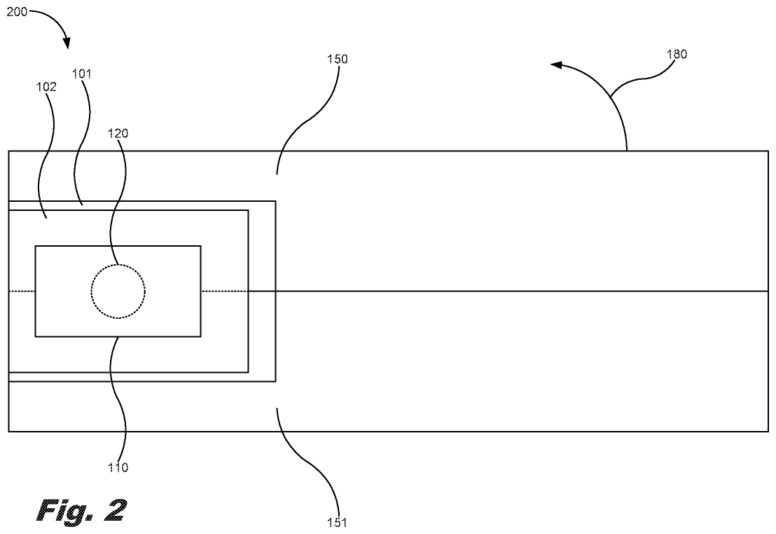

The lid (150) and the base (151) are coupled together using a number of hinges, and, in this configuration create a “clamshell” form factor wherein when the clamshell form factor computing device (100) is open, the computing device (100) may be up and ready to be used. The interface components such as the display device (152) and input devices such as the keyboard (153) and touch pad (154) are kept inside the clamshell, which offers more surface area than when the computing device (100) is closed. The user-interface components such as the keyboard (153), touch pad (154), and display device (152) are protected when the clamshell is closed, and the computing device (100) in this closed configuration is shorter or narrower, making the computing device (100) easier to carry around. The computing device (100) is opened by moving the lid (150) in the direction of arrow (180) with respect to the base (151) as depicted in FIGS. 1 and 2. Likewise, the computing device (100) is closed by moving the lid (150) in the direction of arrow (181) with respect to the base (151) as depicted in FIG. 3.

The computing device (100) may also include a hinge switch (102). The hinge switch (102) may be used to indicate to the remaining hardware of the computing device (100) when the lid (150) is opened. As described herein, when the computing hardware such as a CPU or controller receive a signal from the hinge switch (102) indicating that the lid (150) is opened, the CPU or controller may turn on a number of input and/or output devices such as the display device (152), and input devices such as the keyboard (153) and touch pad (154). In this manner, the hinge switch (102) ensures that the display device (152) remains off or deactivated when not in use to assist in reducing or eliminating image burn-in that may occur if the display device (152) were allowed to remain on when closed. Further, the hinge switch (102) may also ensure that power is not consumed when the display device (152) is not viewable when closed. Still further, the hinge switch (102) may also be used to allow for a user to view outputted data via the display device (152) and/or provide input to the computing device (100) via the keyboard (153) and touch pad (154).

The hinge switch (102) includes a first electrical contact (110) coupled to the lid (150), and a second electrical contact (120) coupled to the base (151). In one example, the second electrical contact (120) may be axially alignable with the first electrical contact (110) to form a physical connection. In another example, the second electrical contact (120) may be linearly alignable with the first electrical contact (110) to form the physical connection. The formation of the physical connection defines a position of the lid (150) relative to the base (151). For example, when the first electrical contact (110) is aligned with and electrically coupled to the second electrical contact (120), the signal to the CPU or controller may indicate that the lid (150) is closed and actions such as powering the display device (152) within the lid (150) and inputs by a user at the keyboard (153) or touch pad (154) may not be recognized. Conversely, when the first electrical contact (110) is not aligned with and electrically coupled to the second electrical contact (120), the signal to the CPU or controller may indicate that the lid (150) is opened and actions such as powering the display device (152) within the lid (150) and inputs by a user at the keyboard (153) or touch pad (154) may be processed by the CPU or controller.

FIG. 2 is a block diagram of a computing device (200) including a hinge switch (102), according to an example of the principles described herein. The computing device (200) of FIG. 2 includes elements similar to the elements described in connection with FIGS. 1 and 3, and description of these similar elements are provided herein. The example of FIG. 2 may also include a hinge (101). The hinge (101) may be any device that rotatably couples the lid (150) to the base (151). The hinge (101) may by any mechanical bearing that connects the lid (150) and the base (151) and allows an angle of rotation between the lid (150) and the base (151). In one example, the computing device (100, 200) may include a plurality of hinges (101) as depicted by circles A depicted in FIG. 3. In an example where the computing device (100, 200) includes a plurality of hinges (101), at least one of the hinges (101) includes a hinge switch (102).

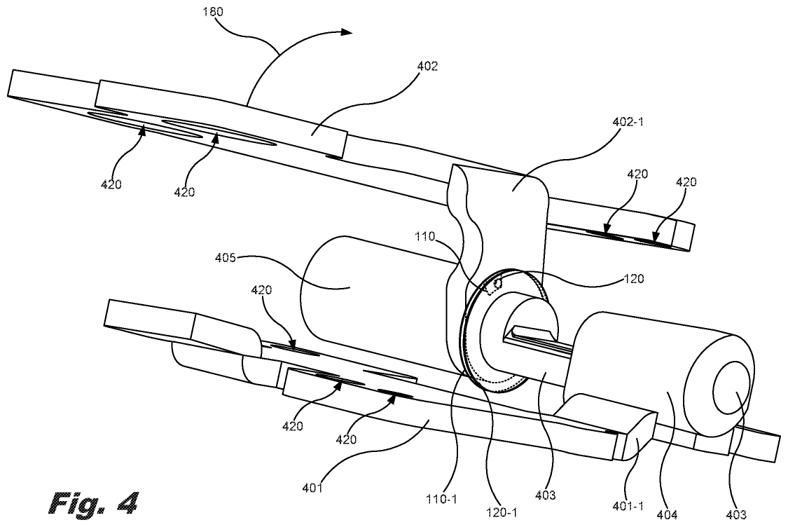

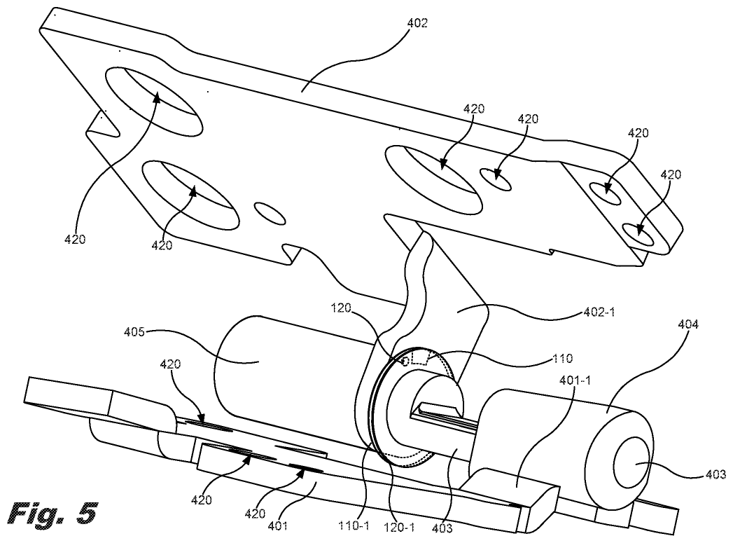

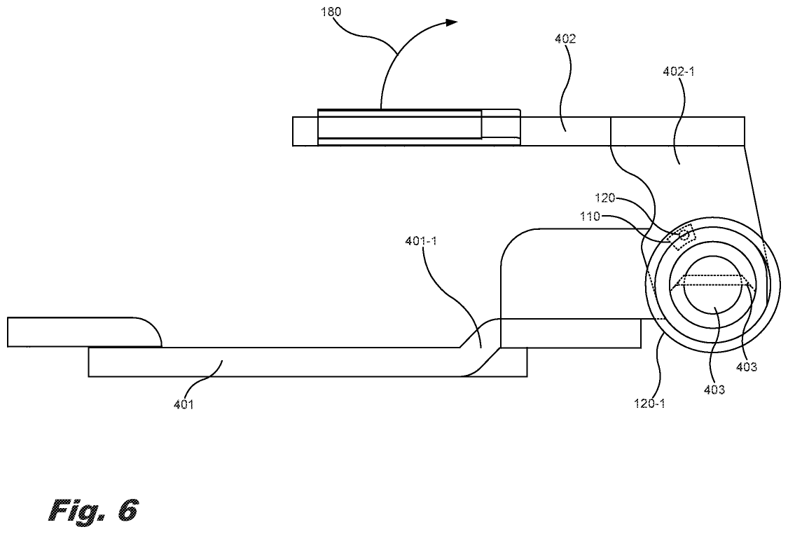

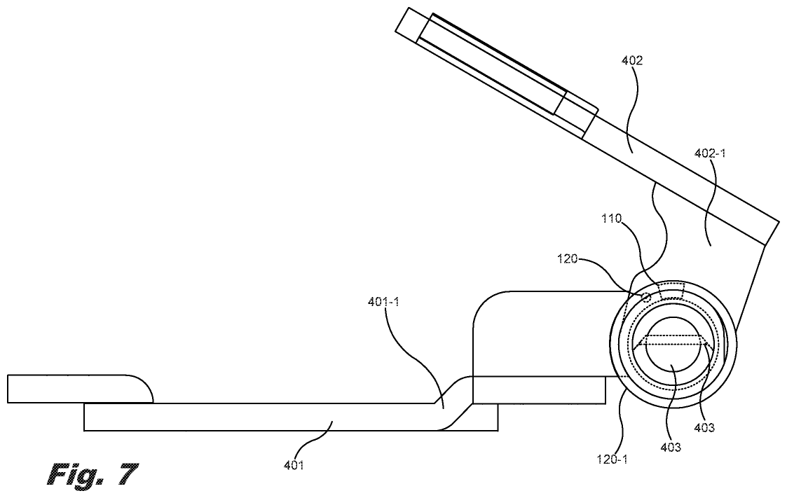

The function of the hinge (101) and hinge switch (102) will be described in connection with FIGS. 4 through 7. FIG. 4 is a perspective view of a hinge switch (102) in a closed orientation, according to an example of the principles described herein. Further, FIG. 5 is a perspective view of the hinge switch (102) in an opened orientation, according to an example of the principles described herein. Still further, FIG. 6 is an elevational view of the hinge switch (102) in a closed orientation, according to an example of the principles described herein, and FIG. 7 is an elevational view of the hinge switch (102) in an opened orientation, according to an example of the principles described herein.

As depicted in FIGS. 4 through 7, the hinge (101) may include a hinge pin (403) housed in a first barrel (404). The hinge pin (403) and the first barrel (404) are mechanically coupled to one another such that the barrel (404) serves as an anchor that couples the hinge pin (403) to a first arm (401). The first arm (401) may be coupled to the first barrel (404) via a first connection arm (401-1). A second barrel (405) may be rotatably coupled to the hinge pin (403). The second barrel (405) is coupled to a second arm (402) via a second connection arm (402-1). In one example, the second barrel (405) may be a pneumatic barrel, or a barrel that uses or includes a friction washer so that as a user opens and closes the lid (150) with respect to the base (151), the friction washer slows down or arrests the movement of the lid (150) relative to the base (151).

The first arm (401) is mechanically coupled to a housing, mount, or other structure element of the base (FIGS. 1-3, 151). Similarly, the second arm (402) is mechanically coupled to a housing, mount, or other structure element of the lid (FIGS. 1-3, 150). In this manner, the first arm (401) and the second arm (402) are able to move the lid (150) with respect to the base (151). As depicted in FIGS. 4 and 6, the first arm (401) is relatively parallel with the second arm (402) in the closed state, and in FIGS. 5 and 7, the first arm (401) is positioned at an angle relative to the second arm (402) in the open state. The first arm (401) and the second arm (402) may include a number of coupling holes (420) through which fasteners such as screws or rivets may be extended to couple the first arm (401) and the second arm (402) to the lid (150) and base (151), respectively.

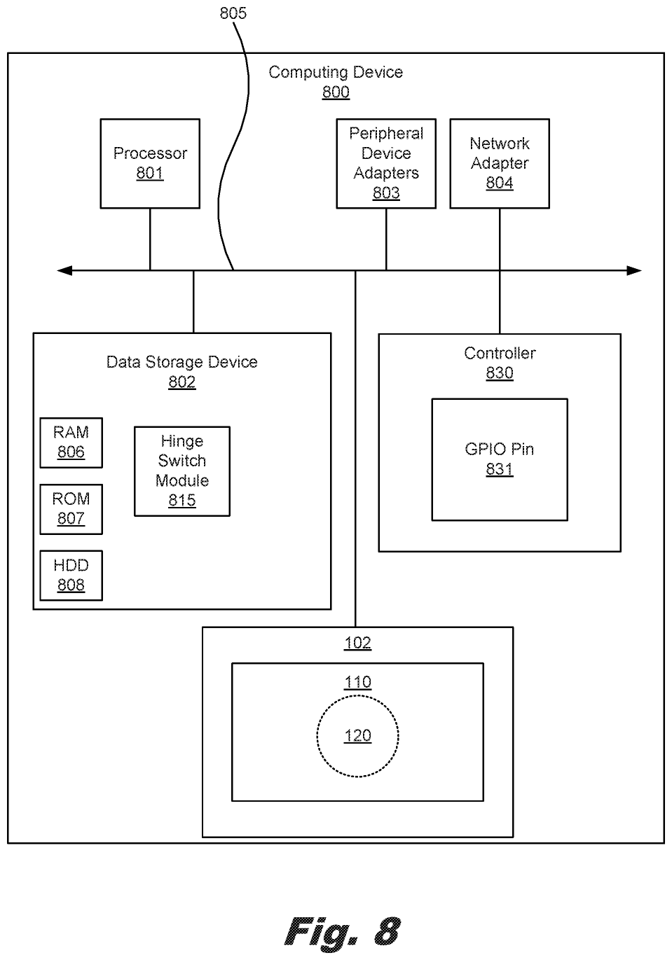

The hinge switch (102) may include a first substrate (110-1) coupled to the second connection arm (402-1). The first substrate (110-1) is able to rotate around the hinge pin (403) as a hole is formed in the first substrate (110-1). A first electrical contact (110) is formed on the first substrate (110-1). The first electrical contact (110) may be electrically coupled to hardware included in the computing device (100, 200) such as a controller (FIG. 8, 830). In an example, the first electrical contact (110) may be electrically coupled to a general-purpose input/output (GPIO) pin (FIG. 8, 831) of the controller (FIG. 8, 830). Signals received from the first electrical contact (110) indicate to the controller (FIG. 8, 830) whether the lid (150) is or is not closed with respect to the base (151).

The hinge switch (102) may also include a second substrate (120-1) coupled to the hinge pin (403). The second substrate (120-1) remains stationary with respect to the hinge pin (403) and the first barrel (404) A second electrical contact (120) is formed on the second substrate (120-1). The second electrical contact (120) may be electrically coupled to ground such that the physical and electrical coupling between the first electrical contact (110) and the second electrical contact (120) complete a circuit to the hardware included in the computing device (100, 200) including the controller (FIG. 8, 830). In an example, when the first electrical contact (110) and the second electrical contact (120) create the circuit, a signal may be sent via the complete circuit to the controller (FIG. 8, 830) to indicate to the controller (FIG. 8, 830) that the lid (150) is in a closed position with respect to the base (151). Conversely, when the first electrical contact (110) and the second electrical contact (120) do not create the circuit, the signal to the controller (FIG. 8, 830) may be interrupted which indicates to the controller (FIG. 8, 830) that the lid (150) is in an open position with respect to the base (151).

As depicted in FIGS. 4 through 7, the first substrate (110-1) and the second substrate (120-1) rotate about the hinge pin (403) with respect to one another. In other words, as the second substrate (120-1) remains stationary about the hinge pin (403), the first substrate (110-1) rotates about the hinge pin (403) along with the second arm (402) and second connection arm (402-1). In this manner, the first electrical contact (110) and the second electrical contact (120) move with respect to one another as the lid (150) moves in the direction of arrows 180 and 181. As the first substrate (110-1) and the second substrate (120-1) rotate about the hinge pin (403), the first electrical contact (110) coupled to the first substrate (110-1) comes in and out of alignment with and physical and electrical coupling to the second electrical contact (120) coupled to the second substrate (120-1).

In an example, the distance the first electrical contact (110) covers in order to clear the second electrical contact (120) and no longer form a physical and electrical connection defines when the computing device (100, 200) will take an action associates with the opening of the lid (150) such as, for example, activating the display device (152). For example, this distance may translate into the display device (152) being activated at a predetermined rotational angle of the display device (152) relative to the base (151) and may be at any point along the angular rotation of the lid (150) with respect to the base (151). In the examples described herein and depicted in FIGS. 1, 2, and 4 through 7, the first electrical contact (110) may include a trapezoidal-shaped plate formed on a portion of the first substrate (110-1). The second electrical contact (120) may include a circular, domed electrical contact formed on and protruding from the second substrate (120-1).

A distance may be present between the first substrate (110-1) and the second substrate (120-1) to accommodate for the protruding, domed second electrical contact (120). As the lid (150) is opened, the second arm (402), second connection arm (402-1), and the first substrate (110-1) rotates relative to the second substrate (120-1). As this movement occurs as indicated by arrow 180 in FIGS. 1, 2, 4 and 6, the first electrical contact (110) moves out of alignment with the second electrical contact (120), and the physical and electrical connection between the first electrical contact (110) and the second electrical contact (120) is disconnected. Conversely, as this movement occurs in the opposite direction as indicated by arrow 181 in FIG. 3, the first electrical contact (110) moves into alignment with the second electrical contact (120), and the physical and electrical connection between the first electrical contact (110) and the second electrical contact (120) is created. This movement is identifiable by comparing the position of the first electrical contact (110) relative to the second electrical contact (120) in FIGS. 4 and 6 as compared to FIGS. 5 and 7.

Having described the manner in which the first electrical contact (110) and the second electrical contact (120) are connected and disconnected through rotation of the lid (150) with respect to the base (151) about the hinge (101), FIG. 8 is a block diagram of a computing device (800) including logic to detect activation and deactivation of a hinge switch (102), according to an example of the principles described herein. The computing device (800) may be utilized in any data processing scenario. To achieve its desired functionality, the computing device (800) includes various hardware components. Among these hardware components may be a number of processors (801), a number of data storage devices (802), a number of peripheral device adapters (803), a number of network adapters (804), a controller (830), and a hinge switch (102), among other devices. These hardware components may be interconnected through the use of a number of busses and/or network connections. In one example, the hardware components may be communicatively coupled via a bus (105).

The processor (801) may include the hardware architecture to retrieve executable code from the data storage device (802) and execute the executable code. The executable code may, when executed by the processor (801), cause the processor (801) to implement at least the functionality of monitoring a position of the lid (150) of the computing device (800) relative to a base (151) of the computing device (800) via the hinge switch (102), and in response to a determination that the hinge switch (102) is activated, determining that the position of a lid (150) relative to the base (151) is in a closed state, wherein the hinge switch (102) is activated when the first electrical contact (110) is in physical contact with the second electrical contact (120) to form an electrical connection. The executable code may also, when executed by the processor (801), cause the processor (801) to implement at least the functionality of, in response to a determination that the hinge switch (102) is deactivated, determining that the position of the lid (150) relative to the base (151) is in an opened state, wherein the hinge switch (102) is deactivated when the first electrical contact (110) is offset from the second electrical contact (151). The executable code may also, when executed by the processor (801), cause the processor (801) to implement at least the functionality of, with a basic input/output system (BIOS), monitoring a status at a general-purpose input/output (GPIO) pin (831) of a controller for the first electrical contact (110) physical contacting and physically offset from with the second electrical contact (120), assert a signal to the GPIO pin (831) of the controller when the hinge switch (102) is activated, activate the display device (152) or another element of the computing device (800) in response to a determination that the hinge switch (102) is deactivated, and other functions, according to the methods of the present specification described herein. In the course of executing code, the processor (801) may receive input from and provide output to a number of the remaining hardware units.

The data storage device (802) may store data such as executable program code that is executed by the processor (801) or other processing device. As will be discussed, the data storage device (802) may specifically store computer code representing a number of applications that the processor (801) executes to implement at least the functionality described herein. The data storage device (802) may include various types of memory modules, including volatile and nonvolatile memory. For example, the data storage device (802) of the present example includes Random Access Memory (RAM) (106), Read Only Memory (ROM) (107), and Hard Disk Drive (HDD) memory (108). Many other types of memory may also be utilized, and the present specification contemplates the use of many varying type(s) of memory in the data storage device (802) as may suit a particular application of the principles described herein. In certain examples, different types of memory in the data storage device (802) may be used for different data storage needs. For example, in certain examples the processor (801) may boot from Read Only Memory (ROM) (107), maintain nonvolatile storage in the Hard Disk Drive (HDD) memory (108), and execute program code stored in Random Access Memory (RAM) (106). The data storage device (802) may include a computer readable medium, a computer readable storage medium, or a non-transitory computer readable medium, among others. For example, the data storage device (802) may be, but not limited to, an electronic, magnetic, optical, electromagnetic, infrared, or semiconductor system, apparatus, or device, or any suitable combination of the foregoing. More specific examples of the computer readable storage medium may include, for example, the following: an electrical connection having a number of wires, a portable computer diskette, a hard disk, a random-access memory (RAM), a read-only memory (ROM), an erasable programmable read-only memory (EPROM or Flash memory), a portable compact disc read-only memory (CD-ROM), an optical storage device, a magnetic storage device, or any suitable combination of the foregoing. In the context of this document, a computer readable storage medium may be any tangible medium that can contain, or store computer usable program code for use by or in connection with an instruction execution system, apparatus, or device. In another example, a computer readable storage medium may be any non-transitory medium that can contain, or store a program for use by or in connection with an instruction execution system, apparatus, or device.

The hardware adapters (103, 104) in the computing device (800) enable the processor (801) to interface with various other hardware elements, external and internal to the computing device (800). For example, the peripheral device adapters (103) may provide an interface to input/output (I/O) devices, such as, for example, the display device (152), the keyboard (153), the touch pad (154), a mouse, other I/O devices, and combinations thereof. The peripheral device adapters (103) may also provide access to other external devices such as an external storage device, a number of network devices such as, for example, servers, switches, and routers, client devices, other types of computing devices, and combinations thereof.

The display device (109) may be provided to allow a user of the computing device (800) to interact with and implement the functionality of the computing device (800). The peripheral device adapters (103) may also create an interface between the processor (801) and the display device (109), a printer, or other media output devices. The network adapter (104) may provide an interface to other computing devices within, for example, a network, thereby enabling the transmission of data between the computing device (800) and other devices located within the network.

The computing device (800) further includes a number of modules used in the implementation of the processes and computer program products described herein. The various modules within the computing device (800) include executable program code that may be executed separately. In this example, the various modules may be stored as separate computer program products. In another example, the various modules within the computing device (800) may be combined within a number of computer program products; each computer program product including a number of the modules.

The computing device (800) may include a hinge switch module (815) to, when executed by the processor (801) and/or controller (830), identify the physical and electrical coupling and decoupling of the first electrical contact (110) and second electrical contact (120), assert a signal to the GPIO pin (831) of the controller (830), interpret the signals as indicative of the lid (150) being open with respect to the base (151), and activating a number of elements such as, for example, the display device (152). according to the interpretation of the signals. In the examples described herein, the first electrical contact (110) being physically and electrically coupled to the second electrical contact (120) indicates to the controller (830) and processor (801) that at least one element of the computing device (800) such as, for example, the display device (152), should be activated.

Thus, the hinge switch module (815) serves as a non-transitory computer readable storage medium that includes instructions that when executed cause the controller (830) of the computing device to monitor a position of the lid (150) of the computing device (800) relative to the base (151) of the computing device (800) via the hinge switch (102). As described herein, the hinge switch (102) includes the first electrical contact (110) and the second electrical contact (120). The hinge switch module (815), in response to a determination that the hinge switch (102) is activated, determines that the position of a lid (150) relative to the base (151) is in a closed state. The hinge switch (102) is activated when the first electrical contact (110) is in physical contact with the second electrical contact (120) to form an electrical connection. The hinge switch module (815), in response to a determination that the hinge switch (120) is deactivated, determines that the position of the lid (150) relative to the base (151) is in an opened state. The hinge switch (102) is deactivated when the first electrical contact (110) is offset from the second electrical contact (120).

The computer program product of the hinge switch module (815) monitors the position of the lid (150) of the computing device (800) by, with a basic input/output system (BIOS) of the computing device (800), monitoring a status at the general-purpose input/output (GPIO) pin (831) of the controller (830) for the first electrical contact (110) physically contacting and physically offset from with the second electrical contact (120).

The computer program product of the hinge switch module (815) may include instructions that when executed cause the controller (830) of the computing device (800) to assert a signal to the GPIO pin (831) of the controller (830) when the hinge switch (102) is activated, and activate the display device (152), for example, in response to a determination that the hinge switch (102) is deactivated.

The specification and figures describe a computing device. The computing device may include a lid, a base, and a hinge switch. The hinge switch includes a first electrical contact coupled to the lid, and a second electrical contact coupled to the base. The second electrical contact is axially alignable with the first electrical contact to form a physical connection. The formation of the physical connection is to define a position of the lid relative to the base.

Through the use of the hinge switch, various elements of a laptop computing device may be activated when the lid of the computing device is opened with respect to a base.

The preceding description has been presented to illustrate and describe examples of the principles described. This description is not intended to be exhaustive or to limit these principles to any precise form disclosed. Many modifications and variations are possible in light of the above teaching.

What is claimed is:

1. A computing device, comprising:
a lid;
a base;
a hinge switch comprising:
a first electrical contact coupled to the lid; and
a second electrical contact coupled to the base, wherein the second electrical contact is axially alignable with the first electrical contact to form a physical connection,
wherein the formation of the physical connection is to define a position of the lid relative to the base.

2. The computing device of claim 1, further comprising:
a hinge; and
a hinge pin, wherein:
the first electrical contact is coupled to a first substrate that is rotatable around the hinge pin,
the second electrical contact is coupled to a second substrate, the second substrate being coupled to the hinge pin, and
the first electrical contact and the second electrical contact are rotatable about the same axis as the hinge coupled between the lid and the base rotates.

3. The computing device of claim 1, further comprising:
a controller comprising a general-purpose input/output (GPIO) pin, wherein:
the first electrical contact is electrically coupled to the GPIO pin,
the second electrical contact is electrically coupled to ground,
the first electrical contact is aligned with the second electrical contact to establish a physical and electrical connection when the computing device is in a closed configuration, and
the establishment of the electrical connection is to complete a circuit to the GPIO to indicate that the computing device is in the closed configuration.

4. The computing device of claim 2, comprising:
a first arm rotatably coupled to the hinge pin, wherein the first substrate is coupled to the first arm; and
a second arm coupled to the hinge pin,
wherein the first arm is coupled to the lid of the computing device, and
wherein the second arm is coupled to the base of the computing device.

5. The computing device of claim 1, wherein:
the first electrical contact is offset from the second electrical contact when the computing device is in an open configuration; and
the offset is to create an open circuit with respect to the GPIO to indicate that the computing device is in the open configuration.

6. The computing device of claim 1, wherein the second electrical contact comprises a protrusion that abuts the first electrical contact when the first electrical contact and the second electrical contact establishes a physical connection.

7. A computing device, comprising:
a lid portion;
a base portion;
a hinge coupling the lid portion and the base portion; and
a hinge switch coupled to the hinge, the hinge switch comprising:
a first electrical contact; and
a second electrical contact axially alignable with the first electrical contact,
wherein a physical engagement of the first electrical contact and the second electrical contact is to define a closed state of the computing device, and
wherein a physical separation of the first electrical contact and the second electrical contact is to define an opened state of the computing device.

8. The computing device of claim 7, wherein:
the first electrical contact is coupled to a first substrate, the first electrical contact being electrically coupled to a general-purpose input/output (GPIO) pin of a controller; and
the second electrical contact is coupled to a second substrate, the second electrical contact to establish an electrical contact to ground,
wherein the first electrical contact and the second electrical contact are physically engaged when the first substrate and the second substrate rotatably align the first electrical contact and the second electrical contact when the computing device is in a closed configuration, the physical engagement of the first electrical contact and the second electrical contact to complete a circuit to the GPIO to indicate that the computing device is in the closed configuration.

9. The computing device of claim 8, wherein:
the first substrate is rotatably disposed around a hinge pin,
the second substrate is coupled to the hinge pin, and
the first substrate and the second substrate rotate about the same axis relative to one another to physically couple and offset the first electrical contact and the second electrical contact.

10. The computing device of claim 7, comprising a state module to determine a state of the computing device based on a signal sent to the GPIO of the controller, wherein the state is the opened state or the closed state.

11. The computing device of claim 8, wherein the hinge comprises:
a hinge pin, the first substrate being rotatable around the hinge pin and the second substrate being coupled to the hinge pin;
wherein the second substrate remains stationary as the first substrate rotates with an arm coupling the lid portion and the first substrate.

12. The computing device of claim 11, wherein the arm comprises a void defined therein through which the hinge pin is extended, the arm being rotatably disposed about the hinge pin.

13. A non-transitory computer readable storage medium comprising instructions that when executed cause a controller of a computing device to:
monitor a position of a lid of the computing device relative to a base of the computing device via a hinge switch;
the hinge switch comprising:
a first electrical contact; and
a second electrical contact;
in response to a determination that the hinge switch is activated, determine that the position of a lid relative to the base is in a closed state, wherein the hinge switch is activated when the first electrical contact is in physical contact with the second electrical contact to form an electrical connection; and
in response to a determination that the hinge switch is deactivated, determine that the position of the lid relative to the base is in an opened state, wherein the hinge switch is deactivated when the first electrical contact is offset from the second electrical contact.

14. The non-transitory computer readable storage medium of claim 13, wherein monitoring the position of the lid of the computing device comprises:
with a basic input/output system (BIOS), monitoring a status at a general-purpose input/output (GPIO) pin of a controller for the first electrical contact physically contacting and physically offset from with the second electrical contact.

15. The non-transitory computer readable storage medium of claim 14, comprising instructions that when executed cause the controller of the computing device to:
assert a signal to the GPIO pin of the controller when the hinge switch is activated;
activate the display device in response to a determination that the hinge switch is deactivated.
